(19) United States
(12) Patent Application Publication
(10) Pub. No.: US 2006/0238985 A1
(43) Pub. Date: Oct. 26, 2006

(54) Heat dissipating assembly using liquid as a heat dissipating medium

(76) Inventor: Chia-Chun Cheng, Chung-Ho City (TW)

Correspondence Address: Rabin & Berdo, P.C., Suite 500, 1101 14th Street, Washington, DC, 20005, US

(21) Appl. No.: 11/403,949

(22) Filed: Apr. 14, 2006

(30) Foreign Application Priority Data
Apr. 21, 2005 (TW) 094206291

(51) Int. Cl. H05K 7/20

(52) U.S. Cl. 361/704

(57) ABSTRACT

A heat dissipating assembly includes a first cover and a second cover securely connected to the first cover. The first cover has a substantially U-shaped configuration and two first tube connecting portions formed on two ends thereof and a first arcuate path defined therein. The second cover has a substantially U-shaped configuration and two second tube connecting portions formed on two ends thereof to correspond to the two first tube connecting portions to respectively define a first tube receiving space to securely receive therein an inlet pipe and a second tube receiving space to securely receive therein an outlet pipe and a second arcuate path defined therein to correspond to the first arcuate path.

### BACKGROUND OF THE INVENTION

1. Field of the Invention

The present invention relates to a heat dissipating assembly, and more particularly to a heat dissipating assembly using liquid as a heat dissipating medium.

2. Description of the Prior Art

Electronic devices, e.g. Central Processing Unit (CPU), Video Graphic Array (VGA) and the like, have been largely used in information technology industry to enhance the operational speed and capability. During operation, the electronic device generates high temperature, which somewhat hinders the operational speed and may even cause damage to the files in processing. In order to avoid such damage to the electronic accessories and the files, most electronic device is provided with a heat dissipating assembly to effectively dissipate heat. The most common heat dissipating assembly now available in the market is the combination of a fan and a fin assembly. Currently, a heat dissipating assembly is introduced to the market using liquid as a heat dissipating medium and composed of a tank, a pump received in the tank, an inlet pipe in communication with the tank and an outlet pipe in communication with the inlet pipe via the tank. Therefore, after the heat dissipating assembly is securely attached to a side of a heat generating electronic device, the liquid inside the tank is able to carry the heat generated by the electronic device and dissipate it while traveling through the outlet pipe. The structure of such a heat dissipating assembly is shown in FIGS. 1 and 2, wherein the conventional heat dissipating assembly is composed of a base (102) securely attached to a cover (101) on top of the base (102), an inlet connector (103) and an outlet connector (104) in communication with the inlet pipe (103) via a space defined between the base (102) and the cover (101). The cover (101) is securely connected to the base (102) via threaded bolts (1011) and a seal (not shown) is normally sandwiched between the base (102) and the cover (101) to prevent leakage. Although this kind of heat dissipating assembly is widely applied in different fields, drawbacks exist, which are listed as follows:

(1) a seal has to be applied between the cover (101) and the base (102) or there will be a leakage;

(2) the inlet pipe (103) and the outlet pipe (104) are orthogonally mounted on the cover (101), the process required to secure the inlet pipe (103) as well as the outlet pipe (104) is troublesome and lengthy;

(3) in order to securely mount the inlet pipe and the outlet pipe on top of the cover (101), a certain length of both the inlet pipe (103) and the outlet pipe (104) is extended out of the bottom face of the cover (101), which causes an uneven path for liquid flow inside the space between the cover (101) and the base (102) and bubbles (A) generate; and

(4) too many parts, which causes lengthy assembling process.

To overcome the shortcomings, the present invention tends to provide an improved heat dissipating assembly to mitigate the aforementioned problems.

### SUMMARY OF THE INVENTION

The primary objective of the present invention is to provide an improved heat dissipating assembly having an arcuate configuration to smoothen liquid flow inside the assembly so as to obviate the possibility of generating bubble inside the assembly.

Another objective of the present invention is that multiple fins are sandwiched between a first cover and a second cover to define paths so as to facilitate liquid flow inside the assembly of the present invention.

Still another objective of the present invention is that the first cover has two first tube connecting portions and the second cover has two second tube connecting portions. After the combination of the first cover and the second cover and insertion of an inlet pipe and an outlet pipe, a smooth inner surface is formed inside the space defined between the first cover and the second cover.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of a conventional heat dissipating assembly;

FIG. 2 is a partially cross-sectional view of the conventional heat dissipating assembly;

FIG. 3 is an exploded perspective view of the heat dissipating assembly of the present invention;

FIG. 4 is a perspective view showing the combination of the heat dissipating assembly of the present invention;

FIG. 5 is a schematic cross sectional view showing the inner structure of the heat dissipating assembly of the present invention;

FIG. 6 is an exploded cross sectional view showing another embodiment of the present invention;

FIG. 7 is an exploded cross sectional view showing still another embodiment of the present invention;

FIG. 8 is a schematic side plan view showing the application of the heat dissipating assembly;

FIG. 9 is a schematic side plan view showing that the heat dissipating assembly of the present invention is applied to dissipate heat from an electronic device; and

FIG. 10 is a schematic top plan view showing that the heat dissipating assembly of the present invention is applied to a heat dissipating system.

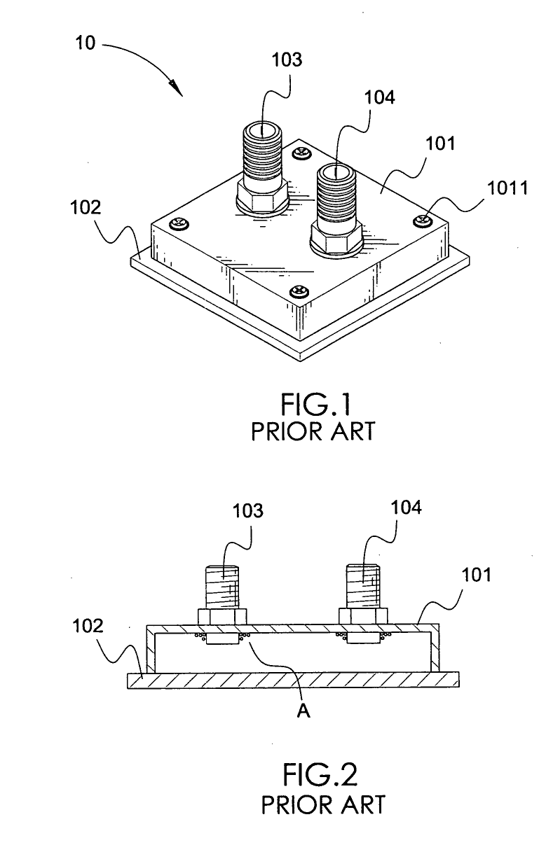

### DETAILED DESCRIPTION OF THE PREFERRED EMBODIMENT

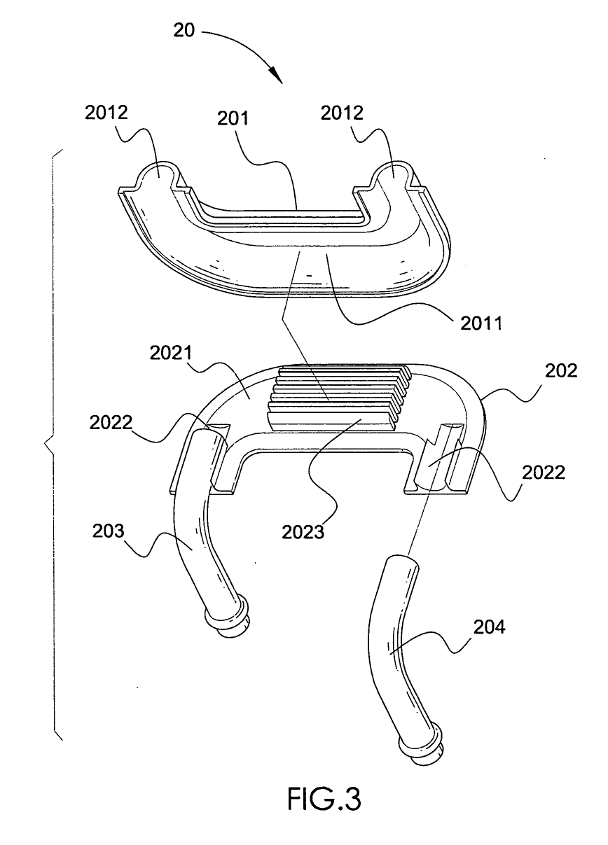

With reference to FIG. 3, it is noted that the heat dissipating assembly (20) in accordance with the present invention includes a first cover (201), a second cover (202), an inlet pipe (203) and an outlet pipe (204).

The first cover (201) is arcuate and has a substantially U-shaped cross section. The first cover (201) has a first arcuate path (2011) defined therein and two first tube connecting portions (2012) formed on two ends thereof.

The second cover (202) is arcuate and has a substantially U-shaped cross section. The second cover (202) has a second arcuate path (2021) defined therein and two second tube connecting portions (2022) defined on two ends thereof. Multiple fins (2023) are rested on a surface of the second cover (202).

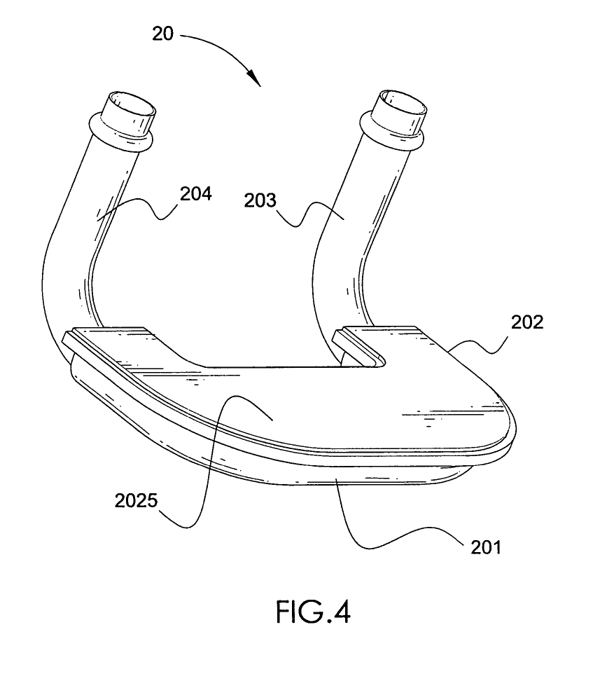

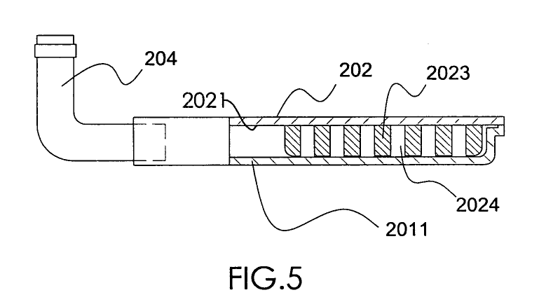

With reference to FIG. 4 and still using FIG. 3 for reference, the first cover (201) and the second cover (202) are able to be combined so that the one of the first tube connecting portions (2012) and one of the second tube connecting portions (2022) are able to form a complete first tube receiving space to receive therein the inlet pipe (203). Accordingly, the combination of the other one of the first tube connecting portions (2012) and the other one of the second tube connecting portions (2022) are able to form a complete second tube receiving space to receive therein the outlet pipe (204).

With reference to FIG. 5, it is noted that after the combination of the first cover (201) and the second cover (202), multiple flow paths (2024) are defined in a space defined by both the first cover (201) and the second cover (202) due to the existence of the fins (2023). Specifically, the flow paths (2024) are defined between the first arcuate path (2011) and the second arcuate path (2021).

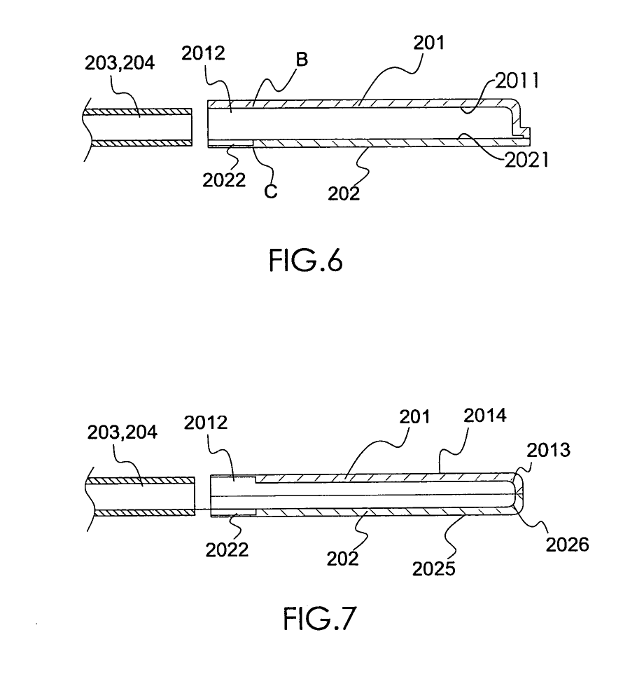

With reference to FIGS. 6 and 7, it is noted that in order to facilitate liquid flow inside the heat dissipating assembly of the present invention, a first step (B) is defined at a joint between the first tube connecting portion (2012) and the first arcuate path (2011) and a second step (C) is defined at a joint between the second tube connecting portion (2022) and the second arcuate path (2021). A depth of each of the first step (B) and of the second step (C) is substantially the same as a thickness of the inlet pipe (203) and of the outlet pipe (204) such that after the inlet pipe (203) and the outlet pipe (204) are respectively received in the first tube receiving space and the second tube receiving space, a smooth surface is defined inside the combination of the first cover (201) and the second cover (202). Because of the smooth surface in the heat dissipating assembly of the present invention, possibility of generating bubbles while the assembly is applied to an electronic device and liquid is flowing from the inlet pipe (203) to the outlet pipe (204) is obviated. In addition, it is noted that to further diminish the bubble generating possibility in the assembly of the present invention, arcuate corners (2013, 2026) are formed along the combination between the first cover (201) and the second cover (202).

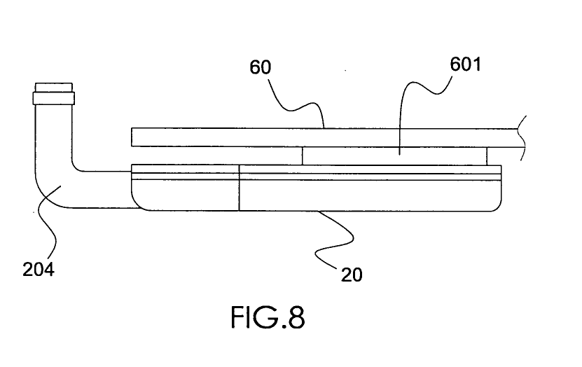

With reference to FIG. 8 and still taking FIG. 4 and FIG. 7 for reference, a heat absorbing surface (2025) is defined in an outer surface of the second cover (202). The heat absorbing surface (2025) is attached to a chip set (601) of a printed circuit board (60) so that heat generated by the chip set (601) is able to be absorbed by the heat absorbing surface (2025) and dissipated while the heat dissipating assembly of the present invention is connected to a liquid cooling system including an pump, pipes etc.

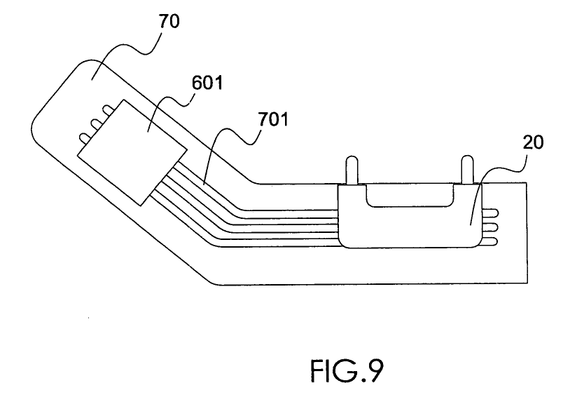

With reference to FIG. 9, it is noted that a heat dissipating seat (70) designed specially for a display interface card has multiple heat dissipating tubes (701) connected to the chip set (601) to carry away the heat from the chip set (601) and the heat dissipating assembly of the present invention is mounted at free ends of the heat dissipating tubes (701) to dissipate the heat from the chip set (601).

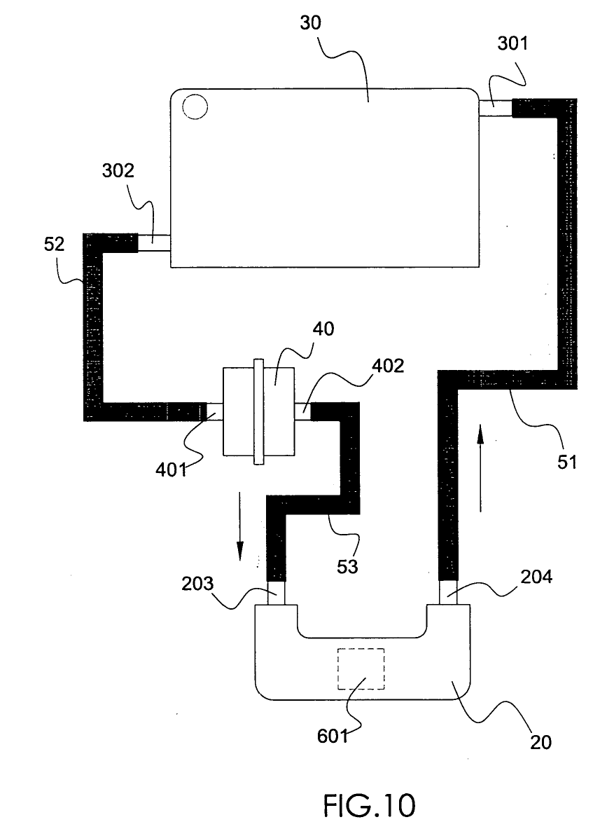

With reference to FIG. 10, a different application of the present invention is shown, wherein the heat dissipating assembly of the present invention is connected to a liquid cooling system having a reservoir (30), an inlet tube (301) in connection to the outlet pipe (204) via a first hose (51), an outlet tube (302) in communication with the inlet tube (301) and connected to an inlet connector (401), via a second hose (52), of a pump (40) which also has an outlet connector (402) connected to the inlet pipe (203) of the present invention via a third hose (53). Thus when the heat dissipating assembly of the present invention is attached to the chip set (601) of a printed circuit board, the heat generated by the chip set (601) is able to be dissipated while the liquid cooling system is in operation.

From the foregoing description, it is noted that the heat dissipating assembly of the present invention has the following advantages:

1. Simple Structure

The entire assembly is composed of a first cover, a second cover, an inlet pipe and an outlet pipe, which obviates the need for a seal and threaded bolts. Accordingly, manufacturing cost is greatly reduced.

2. Stream-Lined Design

A smooth surface is formed inside the space defined between the first cover and the second cover so that after the inlet pipe and the outlet pipe are inserted into the combination of the first cover and the second cover, the liquid flowing therethrough causes no bubbles.

3. Easy Manufacturing

Due to the easy structure of each of the elements, each element is able to directly and easily manufactured.

4. Flat-Panel Design

Because there is a flat-surface (the heat absorbing surface), the overall height of the heat dissipating assembly is greatly reduced such that the heat dissipating assembly is readily attached to a flat-panel designed electronic devices.

5. Securing Element Free

After the first cover and the second cover are combined, the inlet pipe and the outlet pipe are able to be securely received in the first tube receiving space and the second tube receiving space respectively and no additional securing element is required.

In summary, it is to be noted that the inlet pipe and the outlet pipe are able to be securely sandwiched between the first cover and the second cover and a smooth surface is defined inside the combination of the first cover and the second cover such that possibility of generating bubbles in the combination is greatly reduced. Furthermore, the first cover and the second cover are made of the same material so that the combination therebetween is able to achieve the required standard.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipating assembly comprising:
a first cover having a substantially U-shaped configuration and two first tube connecting portions formed on two ends thereof and a first arcuate path defined therein;
a second cover securely attached to the first cover and having a substantially U-shaped configuration and two second tube connecting portions formed on two ends thereof to correspond to the two first tube connecting portions to respectively define a first tube receiving space to securely receive therein an inlet pipe and a second tube receiving space to securely receive therein an outlet pipe and a second arcuate path defined therein to correspond to the first arcuate path.

2. The heat dissipating assembly as claimed in claim 1, wherein multiple fins are sandwiched between the first cover and the second cover to define between the first cover and the second cover multiple flow paths.

3. The heat dissipating assembly as claimed in claim 2, wherein arcuate corners are formed along the combination between the first cover and the second cover.

4. The heat dissipating assembly as claimed in claim 1, wherein a first step is defined at a joint between the first tube connecting portion and the first arcuate path and a second step is defined at a joint between the second tube connecting portion and the second arcuate, a depth of the first step and of the second step is the same as a thickness of the inlet pipe and of the outlet pipe such that after the inlet pipe is securely received in the first tube receiving space and the outlet pipe is securely received in the second tube receiving space, a smooth surface is defined inside the combination between the first cover and the second cover.

5. The heat dissipating assembly as claimed in claim 2, wherein a first step is defined at a joint between the first tube connecting portion and the first arcuate path and a second step is defined at a joint between the second tube connecting portion and the second arcuate, a depth of the first step and of the second step is the same as a thickness of the inlet pipe and of the outlet pipe such that after the inlet pipe is securely received in the first tube receiving space and the outlet pipe is securely received in the second tube receiving space, a smooth surface is defined inside the combination between the first cover and the second cover.

6. The heat dissipating assembly as claimed in claim 3, wherein a first step is defined at a joint between the first tube connecting portion and the first arcuate path and a second step is defined at a joint between the second tube connecting portion and the second arcuate, a depth of the first step and of the second step is the same as a thickness of the inlet pipe and of the outlet pipe such that after the inlet pipe is securely received in the first tube receiving space and the outlet pipe is securely received in the second tube receiving space, a smooth surface is defined inside the combination between the first cover and the second cover.
